(19) United States
(12) Patent Application Publication
(10) Pub. No.: US 2006/0001434 A1
(43) Pub. Date: Jan. 5, 2006

(54) Method of inspecting actual speed of semiconductor integrated circuit

(75) Inventors: Takashi Hiramatsu, Osaka (JP); Kinya Daio, Kyoto (JP); Akiko Fukuda, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/128,331

(22) Filed: May 13, 2005

(30) Foreign Application Priority Data
May 13, 2004 (JP) P. 2004-143208

(51) Int. Cl. G01R 27/00

(52) U.S. Cl. 324/600

(57) ABSTRACT

It is an object to comprehensively carry out an actual speed inspection without reducing an operating speed in a normal mode in a scan test for a semiconductor integrated circuit. In order to operate a circuit at a proper frequency in a shift operation, to operate the circuit in an actual operation time in a capture operation, and to effectively implement different duty ratios from each other for a group of circuits having different operating frequency characteristics in the capture operation, the duty ratios of respective clocks are changed in a shift operation cycle immediately before a capture operation cycle and the respective clocks are set to have an equal duty ratio in a capture operation cycle. In that case, an NT signal control circuit for generating an NT signal to specify the switching of the shift operation and the capture operation is provided in a semiconductor integrated circuit to execute an operation in response to the NT signal within one clock cycle.

### BACKGROUND OF THE INVENTION

1. Field of the Invention

The present invention relates to a method of testing a semiconductor integrated circuit and more particularly to an actual speed inspecting method of detecting a speed failure.

2. Description of the Related Art

A scan test technique and a direct access test technique for a semiconductor integrated circuit have been described in “Designer's Guide to Testable ASIC Devices” written by W. M Needham, Ch. 5, pp. 87-124, Van Nostrand Reinhold, New York 1991. In the test techniques for the semiconductor integrated circuit, it is desirable that all blocks and all signal paths can be tested in a short time, an additional circuit for a test should be small, the number of additional wirings for the test should be small and an operating speed in a normal mode should be prevented from being excessively reduced. A general method using the test techniques is very effective for detecting a degeneration failure in the semiconductor integrated circuit and is currently used widely.

In the case in which the semiconductor integrated circuit is designed by using this method, moreover, it is possible to generate a test program to be used in the shipping inspection of the semiconductor integrated circuit in accordance with a computer program, thereby giving an input signal value and an output expected value in the shipping inspection by means of an LSI tester. In the case in which this method is used, however, a speed is generally decreased more considerably than the actual operation speed of the semiconductor integrated circuit to carry out the inspection. Although the degeneration failure of the semiconductor integrated circuit can be detected, therefore, the speed failure cannot be detected.

As a conventional method of inspecting the actual speed of a semiconductor integrated circuit, there is used a technique for inputting a change in the input terminal of the semiconductor integrated circuit which can be assumed in an apparatus mounting the semiconductor integrated circuit to be an inspecting object to the semiconductor integrated circuit through an LSI tester, thereby evaluating the state of a change in the output terminal of the semiconductor integrated circuit by means of the LSI tester.

Description will be given to the conventional method of inspecting the actual speed of a semiconductor integrated circuit. FIG. 1 is a diagram showing the situation of the surroundings of the semiconductor integrated circuit in the conventional actual speed inspecting method. In FIG. 1, 1 denotes a semiconductor integrated circuit, 2 denotes an input terminal, 3 denotes an output terminal, 4 denotes an input signal line from an LSI tester, 5 denotes an output signal line to the LSI tester, and 6 denotes an external load of the output signal line to the LSI tester.

In the conventional actual speed inspecting method, first of all, the semiconductor integrated circuit 1 is mounted on the LSI tester and an input pattern which can be assumed in the actual machine operation of the semiconductor integrated circuit 1 is input from the input signal line 4 to the input terminal 2. By this input, the semiconductor integrated circuit 1 carries out the same operation as a state in which an operation is performed on an actual machine. The result of the operation of the semiconductor integrated circuit 1 is output from the output terminal 3. The output signal line 5 is connected to the output terminal 3, and the LSI tester compares the state of the output signal line 5 with an output expected value which is prepared, thereby deciding whether the semiconductor integrated circuit 1 is a good product or a defective product.

As the method of inspecting the actual speed of a semiconductor integrated circuit, moreover, there has also been used a technique for providing a built-in self test circuit for diagnosing the failure of a logic portion in the semiconductor integrated circuit and carrying out a built-in self test at an actual operating speed, thereby diagnosing the speed failure of the semiconductor integrated circuit.

In the conventional actual speed inspecting technique, however, there is a problem in that the signal of the output terminal 3 is made dull by the external load 6 of the output signal line of the LSI tester. In general, the external load 6 is much greater than an external load in an actual machine to which the semiconductor integrated circuit 1 is to be mounted. In many cases, therefore, a change in the signal of the output terminal 3 gets out of a clock cycle. For this reason, an output expected value in a portion in which the signal of the output terminal 3 is changed is deleted corresponding to several clock cycles, thereby carrying out an inspection.

FIG. 2 is a timing chart showing an input waveform and an output waveform for a semiconductor integrated circuit in the conventional method of inspecting the actual speed of a semiconductor integrated circuit. In FIG. 2, 7 denotes a clock to be input to the semiconductor integrated circuit 1, 8 denotes an ideal output to be sent from the output terminal 3, 9 denotes an actual output to be sent from the output terminal 3, and 10 denotes an output expected value to be used in the LSI tester.

The semiconductor integrated circuit 1 is operated in response to the clock 7 and tries to output a waveform shown in the ideal output 8 from the output terminal 3. By the influence of the external load 6, however, a dull waveform is output as shown in the actual output 9. In the LSI tester, it is impossible to decide an obscure output signal like the actual output 9. As shown in the output expected value 10, therefore, expected values corresponding to several clocks are deleted from a portion in which an output is regarded to be changed, and a comparison is thus carried out. In the output expected value 10, L represents an expected value having a Low level and X represents a portion in which the comparison of the expected values is not carried out.

Depending on a pattern to be input by the LSI tester, moreover, the whole semiconductor integrated circuit is not operated in many cases. Even if all of the output expected values are compared with each other, only a portion of the semiconductor integrated circuit 1 is inspected. As described above, in the conventional method of inspecting the actual speed of a semiconductor integrated circuit, there is a problem in that the actual speed is guaranteed in only a part of the semiconductor integrated circuit.

### SUMMARY OF THE INVENTION

It is an object of the invention to provide an actual speed inspecting method capable of comprehensively carrying out an actual speed inspection without reducing an operating speed in a normal mode in a test for a semiconductor integrated circuit.

The invention provides a method of inspecting an actual speed of a semiconductor integrated circuit using a scan chain, wherein the circuit is operated at a proper frequency in a shift operation, and the circuit is operated in an actual operation time in a capture operation by clocks for effectively implementing different duty ratios from each other for a group of circuits having different operating frequency characteristics.

According to the actual speed inspecting method, it is possible to operate the circuit in the actual operation time during the capture operation by the clock having an effective duty ratio corresponding to the operating frequency characteristic of the circuit group. Therefore, it is not necessary to add a large scale BIST circuit, to create a test pattern to replay the operation of an actual machine, and to create an individual test pattern for carrying out an actual speed inspection in the circuit portions having different operating frequency characteristics. Thus, it is possible to comprehensively inspect the actual speed of the semiconductor integrated circuit.

In the actual speed inspecting method according to the invention, the clocks for effectively implementing the different duty ratios from each other for the group of circuits having the different operating frequency characteristics are changed in the capture operation and the duty ratios of the respective clocks are changed in a shift operation cycle immediately before a capture operation cycle, and the respective clocks are set to have an equal duty ratio in the capture operation cycle.

According to the actual speed inspecting method, it is possible to effectively implement a clock having a duty ratio corresponding to the operating frequency characteristic of a circuit group while causing the respective clocks to have the equal duty ratio in the capture operating cycle in order to realize the clocks having the different duty ratios while changing the duty ratios of the respective clocks in the shift operation cycle immediately before the capture operation cycle.

In the actual speed inspecting method according to the invention, at least two circuit groups having the different operating frequency characteristics are not connected to the scan chain.

According to the actual speed inspecting method, how to stretch the scan chain across the flip-flops of the circuit groups having the different operating frequency characteristics is avoided. Therefore, it is possible to avoid a possibility that a timing error or a hold error might be generated in the scan chain.

In the actual speed inspecting method according to the invention, a signal (NT signal) for specifying switching of the shift operation and the capture operation is generated for a flip-flop constituting the scan chain by an NT signal control circuit included in the semiconductor integrated circuit.

According to the actual speed inspecting method, the semiconductor integrated circuit includes the NT signal control circuit for generating the NT signal. It is possible to avoid a problem in that the NT signal can be switched corresponding to a clock cycle when the operating frequency of the semiconductor integrated circuit is increased, and a processing is to be carried out in the capture operating cycle and the switching is hard to perform when the NT signal is supplied from an outside. Moreover, the NT signal control circuit can be provided in the most advantageous place in which a delay is minimized. Consequently, it is possible to reduce the delay of the NT signal.

In the actual speed inspecting method according to the invention, the switching of the shift operation and the capture operation is specified by selecting the NT signal generated from the NT signal control circuit or the NT signal given from an outside.

According to the actual speed inspecting method, it is possible to optionally select either the NT signal generated from the NT signal control circuit or the NT signal given from the outside. Therefore, debugging can be carried out in response to the NT signal given from the outside in the case in which a malfunction is caused in the shipping inspection of the semiconductor integrated circuit, for example.

In the actual speed inspecting method according to the invention, the NT signal control circuit is constituted by a counter for generating the NT signal in the capture operation, a reset signal input for initializing the counter, and a count number control input for specifying a count number, and a count of the counter is started after the initialization, an NT signal in one clock cycle is generated when the count number is counted, and the count starting operation after the initialization is returned again to continuously carry out the count.

According to the actual speed inspecting method, there is provided the observing flip-flop for fetching the output of a combinatorial circuit. In the case in which the operating frequency of the semiconductor integrated circuit is increased and it is hard to observe a correct signal at the output terminal in one clock cycle, therefore, it is possible to serially output and observe the contents of the observing flip-flop in the shift operation.

In the actual speed inspecting method according to the invention, an expected value during the capture operation in creation of a test pattern for an inspection is acquired from an output terminal of the scan chain in a scan test for the semiconductor integrated circuit.

In the actual speed inspecting method according to the invention, a test pattern is generated by using the actual speed inspecting method according to the invention for only a circuit portion in which the actual speed is to be guaranteed, and a test pattern is generated by a proper method without depending on the actual speed inspecting method according to the invention for a circuit portion in which the actual speed does not need to be guaranteed.

According to the actual speed inspecting method, a test pattern is generated by using the actual speed inspecting method according to the invention in only a circuit portion in which the actual speed is to be guaranteed, and a test pattern to be executed at the frequency of the shift operation is generated for a circuit in which the actual speed does not need to be guaranteed, for example, and the clock frequency of the LSI tester is switched in accordance with a program. Consequently, it is possible to avoid an extra increase in a cost due to an excessive test.

According to the invention, it is possible to provide an excellent method of inspecting the actual speed of a semiconductor integrated circuit which does not need to add a large scale BIST circuit to influence a development schedule and a unit price of a semiconductor integrated circuit, and can comprehensively test whether or not the semiconductor integrated circuit is operated at an actual operating frequency and can test circuits having different frequencies at the same time also in the case in which they are provided in the semiconductor integrated circuit.

### BRIEF DESCRIPTION OF THE DRAWINGS

FIG. 1 is a diagram showing the surrounding situation of a semiconductor integrated circuit in a conventional actual speed inspecting method,

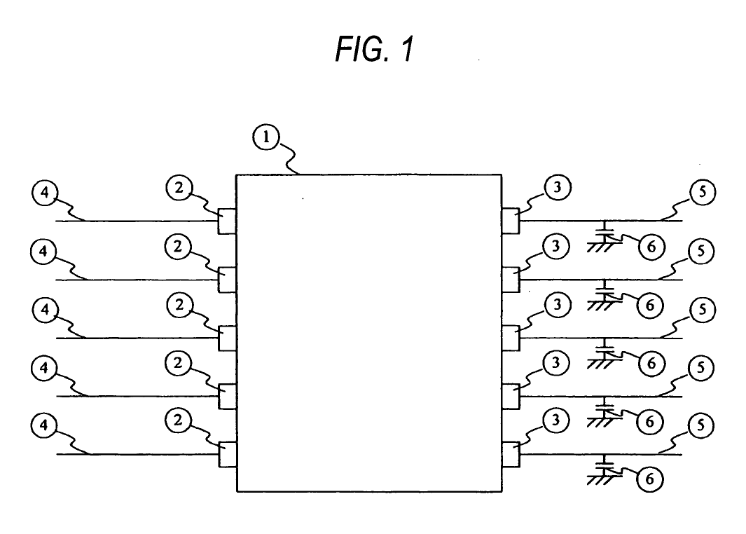

FIG. 2 is a timing chart showing an input waveform and an output waveform for the semiconductor integrated circuit in the conventional actual speed inspecting method,

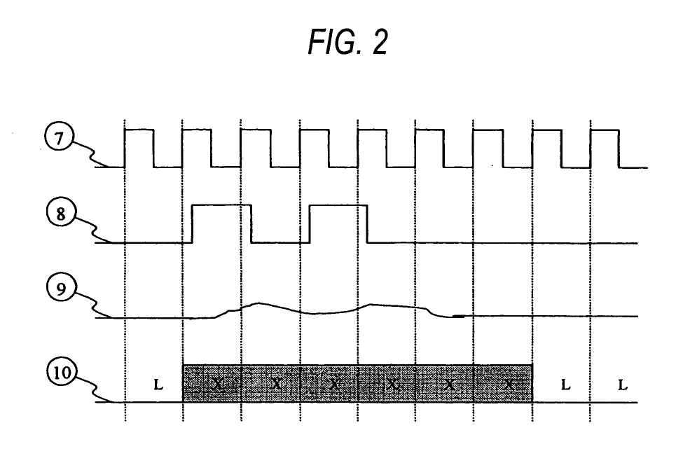

FIG. 3 is a diagram showing the structure of a circuit, illustrating a method of inspecting the actual speed of a semiconductor integrated circuit according to a first embodiment of the invention,

FIG. 4 is a timing chart showing the method of inspecting the actual speed of a semiconductor integrated circuit according to the first embodiment of the invention,

FIG. 5 is a diagram showing the structure of a circuit in the case in which an observing flip-flop is provided on the terminal of a combinatorial circuit connected to the output terminal of the semiconductor integrated circuit according to the first embodiment of the invention,

FIG. 6 is a diagram showing the structure of a circuit, illustrating a method of inspecting the actual speed of a semiconductor integrated circuit according to a second embodiment of the invention,

FIG. 7 is a timing chart showing the method of inspecting the actual speed of a semiconductor integrated circuit according to the second embodiment of the invention,

FIG. 8 is a circuit diagram showing an example of the internal structure of an NT control circuit according to the second embodiment of the invention,

FIG. 9 is a circuit diagram showing an example of the internal structure of a counter capable of controlling a count number according to the second embodiment of the invention, and

FIG. 10 is a timing chart showing the input/output waveform of the counter capable of controlling the count number according to the second embodiment of the invention.

### DESCRIPTION OF THE PREFERRED EMBODIMENTS

### First Embodiment

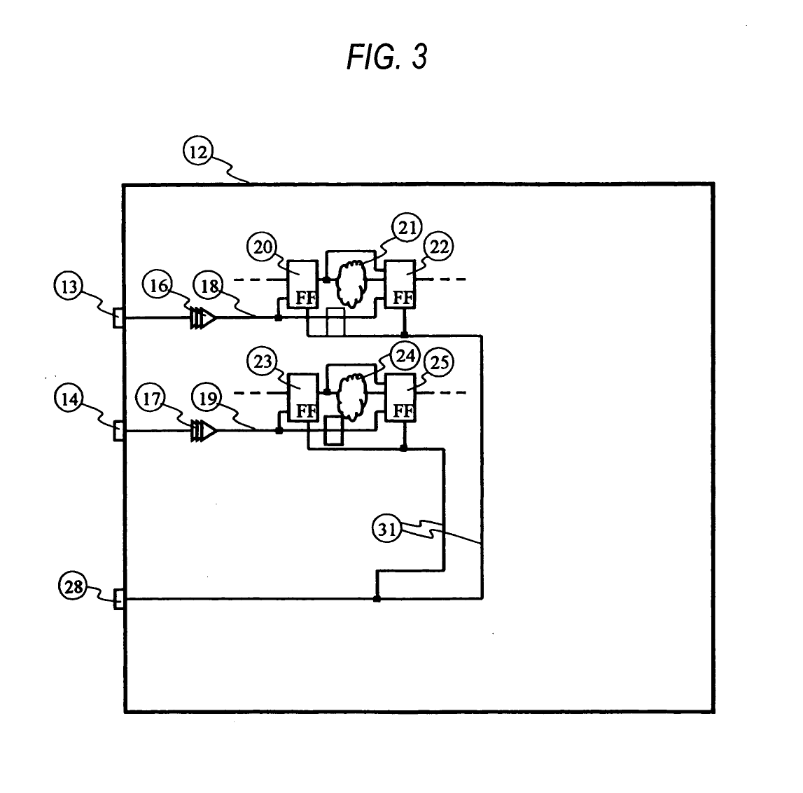

FIG. 3 is a diagram showing the structure of a circuit, illustrating a method of inspecting the actual speed of a semiconductor integrated circuit according to a first embodiment of the invention. In FIG. 3, 12 denotes a semiconductor integrated circuit, 13 and 14 denote first and second clock inputs of the semiconductor integrated circuit 12 respectively, 16 and 17 denote a delay regulating cell for regulating the delays of the first and second clocks respectively, 20 and 22 denote a flip-flop to be operated in response to the first clock, 23 and 25 denote a flip-flop to be operated in response to the second clock, 21 and 24 denote a function logic, and 28 denotes an NT signal input terminal for supplying an NT signal to switch a shift mode and a capture mode in a scan test.

Moreover, 18 and 19 denote output signal lines for the delay regulating cells 16 and 17 which are supplied to the flip-flops 20 and 23, respectively. The outputs of the function logics 21 and 24 are supplied to the flip-flops 22 and 25, respectively. Furthermore, 31 denotes a signal line for supplying an NT signal input from the NT signal input terminal 28 to the lip-flops in the semiconductor integrated circuit 12.

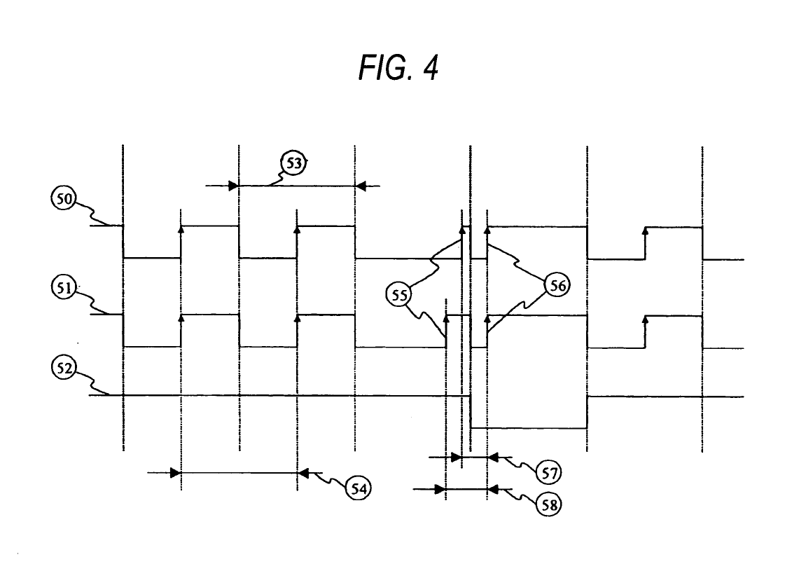

FIG. 4 is a timing chart showing the method of inspecting the actual speed of a semiconductor integrated circuit according to the first embodiment of the invention. In FIG. 4, 50 denotes a waveform of the first clock input 13, 51 denotes a waveform of the second clock input 14, 52 denotes a waveform of the NT signal, 53 denotes a 1-cycle width of the first clock input 13 and the second clock input 14 in a shift operation, and 54 denotes an interval between the leading edges of the first clock input 13 and the second clock input 14 in the shift operation.

Moreover, 55 denotes a leading edge of a clock in a final shift operation of each of the first clock input 13 and the second clock input 14 in the shift operation, 56 denotes a leading edge of a clock in the capture operation of the first clock input 13 and the second clock input 14, 57 denotes an interval between the leading edges of the first clock input 13 in the capture operation, and 58 denotes an interval between the leading edges of the second clock input 14 in the capture operation.

Referring to the method of inspecting the actual speed of a semiconductor integrated circuit having the above-mentioned structure, description will be given to the flow of a signal. First of all, the NT signal input from the NT signal input terminal 28 is set into a shift mode and is supplied to all of the flip-flops on the scan chain via the signal line 31. Since the input of the scan chain is logically cut out of the semiconductor integrated circuit 12, usually, a value for controlling all of the scan flip-flops into optional values is input therefrom.

When all of the flip-flops on the whole scan chain are completely set to have the optional values, the NT signal is set into a capture mode. The interval 54 between the leading edges of the clocks in the shift operation is generally set to be sufficiently great in such a manner that expected values can be stably compared with each other by means of an LSI tester.

The leading edge 56 of the clock in the capture operation is always aligned for the first clock input 13 and the second clock input 14. The operating frequency of the circuit to be operated in response to the first clock input 13 (to which 20 to 22 in FIG. 3 corresponds) is higher than that of the circuit to be operated in response to the second clock input 14 (to which 23 to 25 in FIG. 3 corresponds).

In that case, a phase difference is given to the leading edges of the first clock input 13 and the second clock input 14 in the final shift operation as shown in the leading edge 55. In addition, the interval 57 between the leading edges of the first clock input 13 in the capture operation and the interval 58 between the leading edges of the second clock input 14 in the capture operation are regulated by the delay regulating cell in such a manner that they are equal to the cycles of actual operating frequencies in the respective clocks. Consequently, it is possible to operate the circuit at the actual operating frequency in the capture operation.

On the other hand, the outputs of the semiconductor integrated circuit 12 at the end of the shift operation are generally compared with each other before the clock 56 is input in the capture operation as to whether the combinatorial circuit to be connected to the output terminal of the semiconductor integrated circuit 12 breaks down. More specifically, the output value of the output terminal to be changed by the leading edge 55 is compared with the expected value on this side of the leading edge 56.

In some cases in which the operating frequency of the semiconductor integrated circuit 12 is increased, however, it is hard to obtain a correct signal at the output terminal of the semiconductor integrated circuit 12 within one clock cycle. Therefore, the observing flip-flop is provided on the terminal of the combinatorial circuit connected to the output terminal and a value is fetched therein and is serially output and observed in the shift operation.

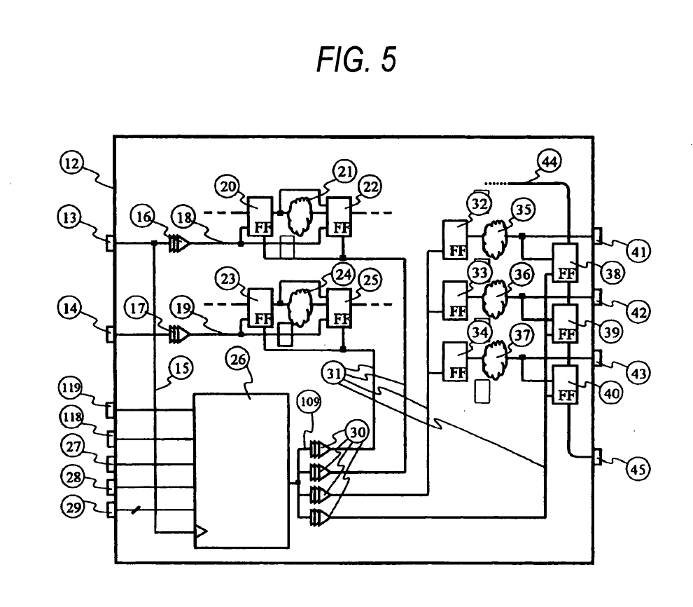

FIG. 5 is a diagram showing the structure of a circuit in the case in which an observing flip-flop is provided on the terminal of the combinatorial circuit connected to the output terminal of the semiconductor integrated circuit according to the embodiment. In FIG. 5, 32 to 34 denote flip-flops for outputting signals to output terminal 41 to 43 through function logics 35 to 37 respectively, and 38 to 40 denote observing flip-flops for fetching a signal output from the output terminals 41 to 43 respectively. Moreover, 44 denotes as can chain passing through the flip-flops 38 to 40, and 45 denotes an output terminal of the scan chain 44.

The output values of the output terminals 41 to 43 which are changed by the leading edge 55 are to be compared with each other on this side of the leading edge 56. However, the width 57 between the leading edge 55 and the leading edge 56 is to be adapted to the actual operating frequency of the semiconductor integrated circuit 12 and an interval is to be reduced very greatly. In many cases, accordingly, a change in the signals of the output terminals 41 and 43 cannot be observed for this period of time.

For this reason, the change in the signals of the output terminals 41 to 43 which is caused by the leading edge 55 is fetched into the observing flip-flops 38 to 40 through the leading edge 56 and is output from the output terminal 45 of the semiconductor integrated circuit 12 through the scan chain 44 passing through the observing flip-flops 38 to 40.

Consequently, the output values sent from the output terminals 41 to 43 in the capture operation are serially output from the output terminal 45 in the shift operation. Thus, it is possible to decide whether or not the flip-flops 32 to 34 and the function logics 35 to 37 are operated at an actual speed. Therefore, it is not necessary to compare the expected values of the output terminals 41 to 43 with each other in a cycle from the leading edge 55 to the leading edge 56.

### Second Embodiment

A data input other than a clock signal in an LSI tester can be usually operated on only the cycle unit of a test pattern. For this reason, in the case in which a clock having a duty regulated is used as described above, it is necessary to operate an NT signal in a very small width from the start of a rate to the input of the clock in a capture cycle and to cause the NT signal to reach all of the scan flip-flops in the semiconductor integrated circuit 12.

When the operating frequency of the semiconductor integrated circuit 12 is increased, however, it is hard to switch the NT signal in a desirable cycle. In order to solve this problem, a circuit for generating the NT signal is mounted in the semiconductor integrated circuit 12, thereby switching the NT signal in the embodiment.

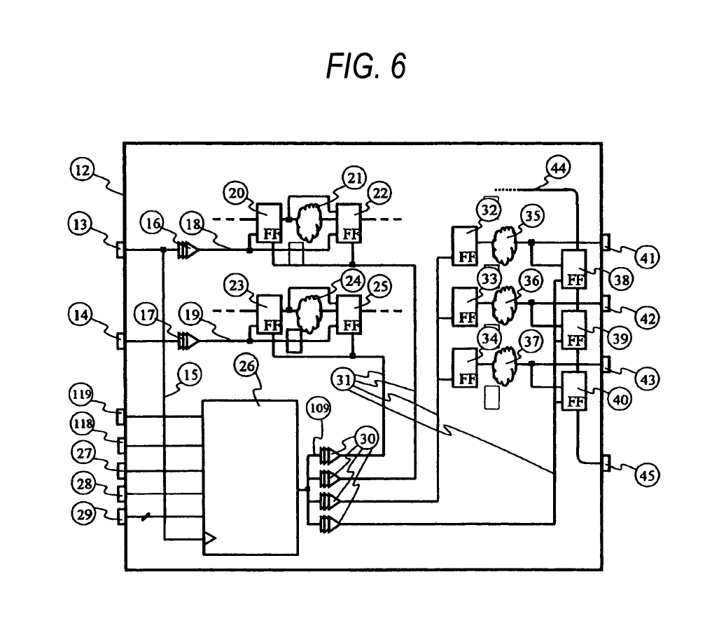

FIG. 6 is a diagram showing the structure of a circuit, illustrating a method of inspecting the actual speed of a semiconductor integrated circuit according to a second embodiment of the invention. In FIG. 6, 15 denotes a signal line of a clock input 13, 26 denotes an NT signal control circuit, 27 denotes an NT path switching terminal for an input to the NT signal control circuit 26, 29 denotes a count number input terminal for inputting a number for counting by means of the NT signal control circuit 26, 30 denotes a delay regulating circuit for regulating the delay of an NT signal output from the NT signal control circuit 26, 109 denotes a signal line of the NT signal output from the NT signal control circuit 26, 118 denotes a reset input terminal of the NT signal control circuit 26, and 119 denotes a mode switching input terminal for causing the NT signal control circuit 26 to switch a normal operation mode or a scan test operation mode.

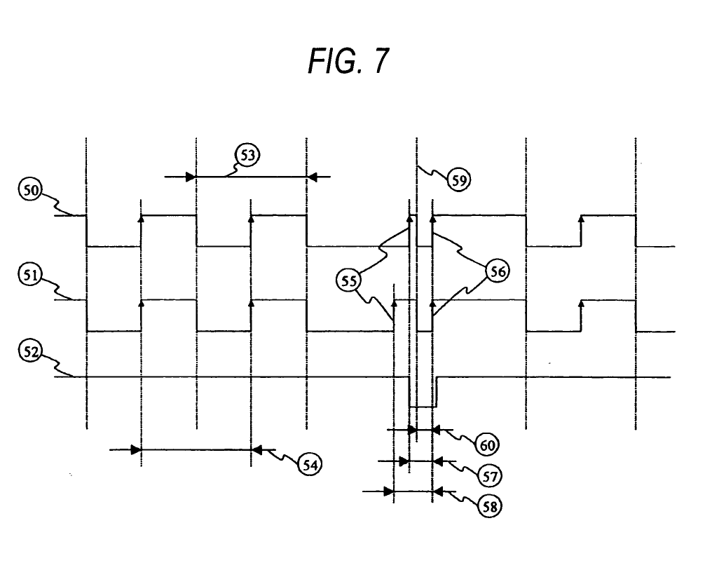

FIG. 7 is a timing chart showing the method of inspecting the actual speed of a semiconductor integrated circuit according to the second embodiment of the invention. In FIG. 7, 59 denotes a starting portion of a rate of a capture operation cycle and 60 denotes an operational allowable width in the case in which the NT signal is directly operated from an outside as in the first embodiment in order to carry out a comparison with an NT signal 52 according to the embodiment.

The details of the embodiment will be described below. First of all, in the case in which a signal input from the mode switching input 119 is set in a normal operation mode, a signal for setting flip-flops in the semiconductor integrated circuit 12 into the normal operation mode is output as the NT signal 109 output from the NT signal control circuit 26.

For example, it is assumed that the normal operation mode is set when the value of the mode switching input terminal 119 is “0”, the scan test operation mode is set when the value is “1”, and furthermore, the internal flip-flops are set into a normal operating state (that is, a capture operating state) when the NT signal is “0” (a capture mode), and a shift operating state is set when the NT signal is “1” (a shift mode), “0” is output to the NT signal 109 so that the semiconductor integrated circuit 12 is brought into the normal operating state even if a signal other than the mode switching signal 119 to be input to the NT signal control circuit 26 has any value in the case in which “0” is input from the mode switching input terminal 119.

In the case in which “1” is input from the mode switching input terminal 119 and the semiconductor integrated circuit 12 is set in the scan test mode, the following operation is carried out. The NT signal control circuit 26 is initialized by a reset input sent from the outside of the semiconductor integrated circuit 12. In the case in which the mode switching input 119 is set in the scan test operation mode, a signal for setting the internal flip-flops of the semiconductor integrated circuit 12 in to the shift mode is output when the initialization is carried out.

The NT signal generated in the NT signal control circuit 26 is supplied to all of the scan flip-flops connected to the whole scan chain in the semiconductor integrated circuit 12 through the delay regulating circuit 30 and a signal line 31. At that time, in the case in which clock systems having different operating frequencies are provided in the semiconductor integrated circuit 12, it is necessary to carry out a separation for each clock system to regulate a delay, the reason of which will be described below. Therefore, a branch is carried out corresponding to the number of the clock systems ahead of the NT signal control circuit 26 and a delay regulating circuit is attached to each of them. In FIG. 6, flip-flops 20 to 22, flip-flops 23 and 25, flip-flops 32 to 34 and flip-flops 38 to 40 are shown to have different operating frequencies from each other.

In many cases, circuits having different operating frequencies generally have a great difference in a scale in the semiconductor integrated circuit. More specifically, the numbers of the flip-flops connected a head of the delay regulating circuits 30 divided for respective clock systems are greatly different from each other, and delay differences made by the signal lines 31 are different from each other. For this reason, it is necessary to carry out a division to regulate a delay as in the delay regulating circuit 30 shown in FIG. 3.

After the initialization, the NT control circuit 26 carries out a count operation corresponding to the number of counts input from the count number input terminal 29, and inverts the NT signal 109 corresponding to one clock cycle every full-count. In the case in which the NT control circuit 26 is not provided, the NT signal can be changed in only the rate starting portion 59 for the capture operation by the features of the LSI tester. Therefore, the operational allowable width 60 is greatly reduced so that a control is to be carried out in a very severe timing. On the other hand, in the case in which the NT signal control circuit 26 is provided, a width 57 is set to be the operational allowable width. Therefore, the width 57 is greater than the width 60 and the NT signal is automatically generated in the semiconductor integrated circuit. Consequently, it is not necessary to consider an external input timing.

In the case in which the NT signal is input from the outside of the semiconductor integrated circuit 12, moreover, a great delay is caused by the input cell of the semiconductor integrated circuit and it is necessary to insert a large number of delay circuits for causing a delay to be equal up to the flip-flop on a chip. In the case in which the NT signal control circuit according to the invention is used, however, it is possible to provide the NT signal control circuit in the most advantageous place in which the delay is reduced. Therefore, the delay of the NT signal can be reduced.

Moreover, the NT signal control circuit 26 is caused to have the NT path switching terminal 27 for directly controlling the NT signal from the outside. By changing the value of the switching terminal 27, it is possible to switch whether the NT signal to be used in the semiconductor integrated circuit 12 is generated in the NT signal control circuit 12 or is input from an NT signal input terminal 28. It is necessary to directly control the NT signal to be controlled in debugging from the outside of the semiconductor integrated circuit 12 when a malfunction is caused in the actual speed inspecting method according to the invention for some reason.

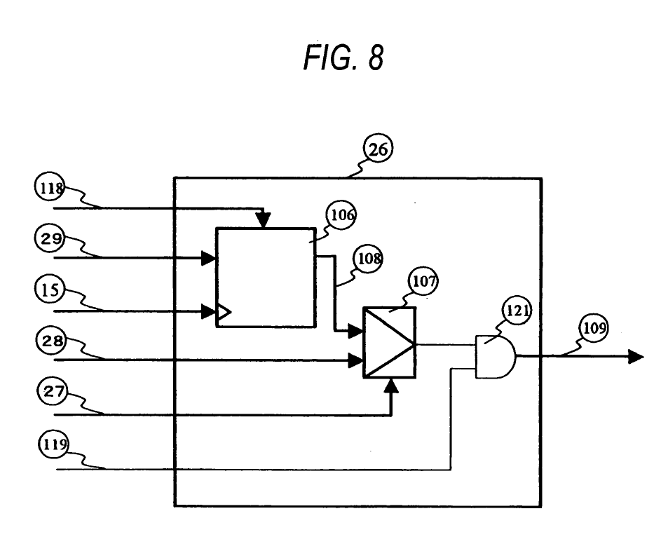

Next, the internal operation of the NT control circuit 26 will be described in detail. FIG. 8 is a circuit diagram showing an example of the internal structure of the NT control circuit 26. In FIG. 8, 106 denotes a counter capable of controlling a count number by the count number input 29, 107 denotes a selector for selecting the NT input signal 28 or the output of the counter 106 as the NT signal, 108 denotes an output signal line of the counter 106, and 121 denotes an AND circuit capable of setting the NT signal 109 into the shift mode only when the mode switching input 119 is set in the scan test operation mode.

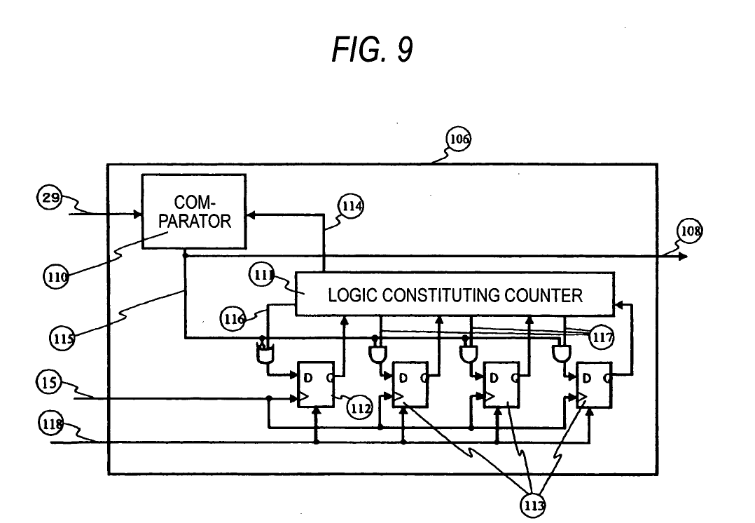

FIG. 9 is a circuit diagram showing an example of the internal structure of the counter 106 capable of controlling a count number. In FIG. 9, 110 denotes a comparator for comparing the output value of a logic 111 constituting the counter with the value of the count number input signal 29, 112 denotes a least significant bit flip-flop constituting the counter, 113 denotes a flip-flop other than the least significant bit 112 constituting the counter, 114 denotes a count output based on the values of the flip-flops 112 and 113, 115 denotes an output signal line of the comparator 110, 116 denotes an output signal line from the logic 111 constituting the counter to the flip-flop 112, and 117 denotes an output signal line from the logic 111 constituting the counter to the flip-flop 113.

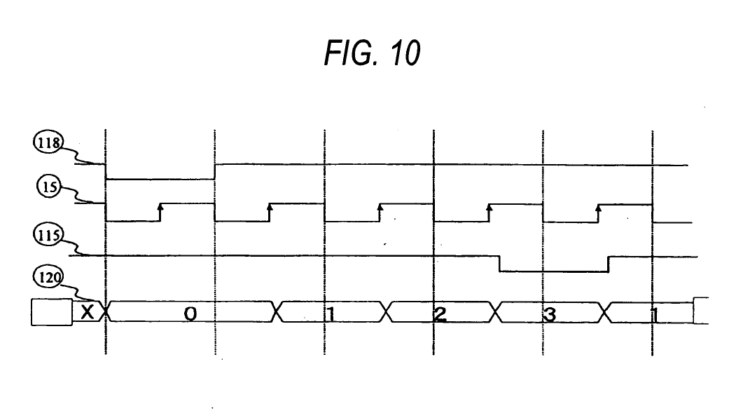

FIG. 10 is a timing chart showing the input/output waveform of the counter 106 capable of controlling a count number. In FIG. 10, 115 denotes an output signal of the comparator 110 indicating that the output value of the logic 111 is coincident with the value of the count number input signal 29, and 120 denotes a value of the count output 114.

In FIG. 9, first of all, the logic 111, the flip-flop 112 and the flip-flop 113 constitute a clock synchronizing type counter, and a count value is increased every time the clock 15 is input. In the flip-flop 112 and the flip-flop 113, a count value is initialized to “0” by the reset 118 and the counter starts count-up by the initial input of the clock 15 after the cancellation of the reset.

A value obtained by adding 1 to the maximum number of the flip-flops connected to the scan chain in the semiconductor integrated circuit 12 is input to the count number input signal 29. The count number input signal 29 and the count output 114 of the logic 111 are input to the comparator 110. The comparator 110 compares the count number control input signal 29 with the count output 114 and outputs a Low level to the output signal line 115 if both of them are coincident with each other.

A logical sum of a signal obtained by inverting the output 115 of the comparator 110 and the output signal line 116 of the logic 111 constituting a counter is input to the D input of the flip-flop 112, and a logical product of the output 115 of the comparator 110 and the output signal line 117 of the logic 111 constituting the counter is input to the D input of the flip-flop 113. By such a structure, it is possible to constitute a counter for subsequently starting the count-up from a count value of “1” when the counter starts the count-up from the initial value of “0” and carries out the count-up to the value of the count number input signal 29.

More specifically, it is possible to constitute a counter in which a count is started from “1” by the initial input of the clock 15 after the count value is initialized to “0” by the reset 118, and the count-up is carried out every time the clock 15 is subsequently input and the count-up is started from the count value of “1” again by the input of the next clock 15 counted up to the number of the flip-flops of the scan chain which is indicated by the count number input signal 29.

The output 115 of the comparator 110 is the same as a signal obtained by advancing the NT input signal by a half cycle in the case in which the actual speed inspecting method according to the invention is not applied to the semiconductor integrated circuit 12. Accordingly, the signal line 115 can be used as the NT signal generated in an optional count number in the invention.

FIG. 10 shows the above description in a waveform. It is assumed that a value of “3” is input from the count number input 29. First of all, the counter is initialized by the input of the reset input 118. At this time, the count value 120 is set to be “0”. In a next cycle in which the reset 118 is cancelled, the count value is started to be counted from “1”. When the count-up is carried out up to “3”, the value of the output 115 from the comparator 110 is set to have a Low level. At a subsequent clock input, “1” is input to the flip-flop 112 and “0” is input to the flip-flop 113. Consequently, the value of the count output 114 is set to be “1”. Subsequently, the operation after the cancellation of the reset 118 is repeated.

The value of the count number input signal 29 is obtained by adding 1 to the maximum number of the flip-flops connected to the scan chain in the semiconductor integrated circuit 12. The reason is that a cycle for carrying out the capture operation is started after the shift operation is ended. If the maximum number of the flip-flops connected to the scan chain is exactly input, a timing for outputting the NT signal is advanced by one cycle.

In FIG. 8, next, the signal 108 output from the counter 106 and the NT signal 28 input from the outside of the semiconductor integrated circuit are input to the selector 107. The selector 107 selects the signal 108 output from the counter 106 or the NT signal 28 in response to the NT path switching signal 27.

In the case in which the signal 108 output from the counter 106 is selected as the NT signal 109, a delay in the semiconductor integrated circuit 12 is more reduced as compared with the case in which the NT signal 28 input from the outside is selected. Also in case of a semiconductor integrated circuit having a high operating frequency, therefore, there is an advantage that a change in the NT ranges within one clock cycle. To the contrary, in the case in which the NT signal 28 to be input from the outside is selected, the NT signal is directly switched from the outside of the semiconductor integrated circuit 12, which is convenient to the case in which debugging is carried out when a malfunction is caused in the shipping inspection of the semiconductor integrated circuit.

Next, description will be given to how to stretch the scan chain in the semiconductor integrated circuit 12 which is a technical common sense. In the case in which a portion having a different clock frequency in the actual operation is present in the semiconductor integrated circuit, it is necessary to stretch the scan chain so as not to cross the flip-flops to be operated in response to clocks having different operating frequencies.

As described above, the leading edges 55 of the first clock input 13 and the second clock input 14 at the end of the shift operation have a phase difference. For this reason, in the case in which there is a scan chain crossing the flip-flops having different operating frequencies, a serious timing error is generated in the scan chain crossing different kinds of clocks when a clock having a phase difference as in the clock edge 55 is input.

In the present example, the circuit to be operated in response to the second clock input 14 is delayed from the circuit to be operated in response to the first clock input 13. In that case, it is apparent that a hold error is generated in a path turned from the flip-flop to be operated in response to the second clock input 14 toward the flip-flop to be operated in response to the first clock input 13. In order to prevent such a condition, a scan chain crossing the flip-flops having the different operating frequencies should not be constituted.

Moreover, the clock edge 56 is a rise in a clock in the capture operation. The rise 56 is carried out in an identical timing in the whole clock system. Although paths are generated between the flip-flops having the different operating frequencies in the capture operation, a hold error is not made if the clock edges 56 are aligned with each other.

Next, description will be given to a method of creating an inspection pattern by an LSI tester in the method of inspecting the actual speed of a semiconductor integrated circuit according to the invention. Usually, there is a path in which the actual speed does not need to be guaranteed in the semiconductor integrated circuit. In particular, this case is often generated in paths between circuits having different clock frequencies.

In the case in which a pattern for a shipping inspection in the semiconductor integrated circuit and the LSI tester is created by using the guarantee of the inspection of the actual speed in the semiconductor integrated circuit according to the invention, whether the whole circuit is operated at an actual speed frequency is examined comprehensively. For this reason, the same test is carried out for circuit portions in which the speed does not need to be guaranteed originally. Consequently, an excessive test is executed. For this reason, a cost is excessively increased.

In order to avoid the foregoing, the pattern creating method is roughly classified in to two parts. As one of the parts, an interval between the leading edge 55 and the leading edge 56 of a clock is set to be equal to an interval between actual speed frequencies, and only a circuit portion in which the actual operating frequency is to be guaranteed is evaluated. As the other part, the interval between the clock edge 55 and the clock edge 56 is maintained to be the width of the interval 54 between the clock edges in the shift operation and only the circuit portion in which the actual operating frequency does not need to be guaranteed is evaluated.

In the case in which the pattern for a shipping inspection is to be automatically generated in accordance with a test pattern generating program, the detection of a failure in any portion is switched according to the classification so that one pattern for a shipping inspection can be generated. Actually, it is possible to easily implement a change in the frequency of an input clock by means of the LSI tester in accordance with the program. In the pattern for a shipping inspection which is generated, therefore, an excessive test can be avoided if a method of inputting a clock is programmed to be the method of inspecting the actual speed of a semiconductor integrated circuit according to the invention in the portion in which the actual speed operation is to be evaluated.

Referring to a comparison between an expected value with the output value of an output terminal in the capture operation, moreover, only a portion subjected to the actual speed inspection can be cut. The reason has been described above. Consequently, it is possible to decide a failure in the circuit portions from the flip-flops 32 to 34 to the output terminals 41 to 43. Thus, it is possible to prevent a reduction in a failure detection rate.

The method of inspecting the actual speed of a semiconductor integrated circuit according to the invention has an advantage that it is possible to comprehensively test whether or not the semiconductor integrated circuit is operated at an actual operating frequency without adding a large scale BIST circuit which influences a development schedule and a unit price of the semiconductor integrated circuit, and to test circuits having different frequencies at the same time also in the case in which they are provided in the semiconductor integrated circuit, and is useful as a test technique for the semiconductor integrated circuit.

What is claimed is:

1. A method of inspecting an actual speed of a semiconductor integrated circuit using a scan chain, wherein the circuit is operated at a proper frequency in a shift operation, and the circuit is operated in an actual operation time in a capture operation by clocks for effectively implementing different duty ratios from each other for a group of circuits having different operating frequency characteristics.

2. The method of inspecting an actual speed of a semiconductor integrated circuit according to claim 1, wherein the clocks for effectively implementing the different duty ratios from each other for the group of circuits having the different operating frequency characteristics are changed in the capture operation and the duty ratios of the respective clocks are changed in a shift operation cycle immediately before a capture operation cycle, and the respective clocks are set to have an equal duty ratio in the capture operation cycle.

3. The method of inspecting an actual speed of a semiconductor integrated circuit according to claim 1, wherein at least two circuit groups having the different operating frequency characteristics are not connected to the scan chain.

4. The method of inspecting an actual speed of a semiconductor integrated circuit according to claim 1, wherein a signal (NT signal) for specifying switching of the shift operation and the capture operation is generated for a flip-flop constituting the scan chain by an NT signal control circuit included in the semiconductor integrated circuit.

5. The method of inspecting an actual speed of a semiconductor integrated circuit according to claim 4, wherein the switching of the shift operation and the capture operation is specified by selecting the NT signal generated from the NT signal control circuit or the NT signal given from an outside.

6. The method of inspecting an actual speed of a semiconductor integrated circuit according to claim 4, wherein the NT signal control circuit is constituted by a counter for generating the NT signal in the capture operation, a reset signal input for initializing the counter, and a count number control input for specifying a count number, and a count of the counter is started after the initialization, an NT signal in one clock cycle is generated when the count number is counted, and the count starting operation after the initialization is returned again to continuously carry out the count.

7. The method of inspecting an actual speed of a semiconductor integrated circuit according to claim 6, wherein the counter is constituted by a flip-flop constituting the counter, a count logic circuit for outputting a count value, and a comparator for comparing a value of the counter with a count number specified by the count number control input, and a value is initialized to zero in response to a reset signal sent to the reset signal input and the count is then started, and a value of 1 is set to continuously carry out the count again after the NT signal in the one clock cycle is output when a coincidence is detected by the comparator.

8. The method of inspecting an actual speed of a semiconductor integrated circuit according to claim 1, wherein a signal (NT signal) for specifying switching of the shift operation and the capture operation for a flip-flop constituting the scan chain is connected through a delay circuit for regulating a delay value for each of the circuit groups having the different operating frequency characteristics.

9. The method of inspecting an actual speed of a semiconductor integrated circuit according to claim 1, wherein an observing flip-flop for inputting an output of a combinatorial circuit which is not connected to any flip-flop but is directly connected to an external terminal is added to the semiconductor integrated circuit and is thus connected to the scan chain.

10. The method of inspecting an actual speed of a semiconductor integrated circuit according to any of claims 1 to 9, wherein an expected value during the capture operation in creation of a test pattern for an inspection is acquired from an output terminal of the scan chain in a scan test for the semiconductor integrated circuit.

11. A method of inspecting an actual speed of a semiconductor integrated circuit, comprising the steps of generating a test pattern by using the method of inspecting an actual speed of a semiconductor integrated circuit according to claim 1 or 2 for only a circuit portion in which the actual speed is to be guaranteed, and generating a test pattern by a proper method without depending on the method of inspecting an actual speed of a semiconductor integrated circuit according to claim 1 or 2 for a circuit portion in which the actual speed does not need to be guaranteed.

12. A semiconductor integrated circuit for executing the actual speed inspecting method according to any of claims 1 to 9.
